(19) United States
(12) Patent Application Publication
(10) Pub. No.: US 2012/0231574 A1
(43) Pub. Date: Sep. 13, 2012

(54) Continuous Electroplating Apparatus with Assembled Modular Sections for Fabrications of Thin Film Solar Cells

(76) Inventor: Jiaxiong Wang, Castro Valley, CA (US)

(21) Appl. No.: 13/046,710

(22) Filed: Mar. 12, 2011

(51) Int. Cl. H01L 31/0256; C25D 17/02; C25D 7/12

(52) U.S. Cl. 438/95; 204/267; 257/E31.003

(57) ABSTRACT

An electroplating production line or apparatus that can be assembled with modular plating sections in a roll-to-roll or reel-to-reel continuous plating process is provided. The length of the plating cell for a modular plating section can be readily changed to fit different current densities required in a roll-to-roll or reel-to-reel process. In addition, the electrolyte solution tanks can be simply connected or disconnected from the modular plating sections and moved around. With these designs, a multiple layers of coating with different metals, semiconductors or their alloys can be electrodeposited on this production line or apparatus with a flexibility to easily change the plating orders of different materials. This apparatus is particularly useful in manufacturing Group IB-IIIA-VIA and Group IIB-VIA thin film solar cells such as CIGS and CdTe solar cells on flexible conductive substrates through a continuous roll-to-roll or reel-to-reel process.

### BACKGROUND

1. Field of the Invention

The present invention relates to a roll-to-roll or reel-to-reel electroplating production line that can be assembled to deposit multiple absorber layers of metal or alloy thin films to fabricate thin film solar cells based on the Group IB-IIIA-VIA or IIB-VIA polycrystalline compounds.

2. Description of the Related Art

With the development of global warming, environmental contaminations and exhausting of fossil fuels, solar cells have attracted more and more attentions as a leading green energy source. Although crystalline silicon based solar cells still dominate the solar cell world market today, thin film solar cells have shown a very promising future due to their low costs, flexibility and capability of large scale industrial manufacture. In this thin film solar cell family, the CIGS solar cells possess the highest conversion efficiency that is as high as 20%, higher than 16% efficiency of the CdTe ones. In the periodic table of the elements, the elements of a CIGS absorber are located in Group IB-IIIA-VIA and the ones of a CdTe absorber in Group IIB-VIA. Owing to their promising future, different techniques have been developed to fabricate these kinds of thin film solar cells. According to the materials and environments in the fabrications, these techniques can be roughly divided into dry and wet two groups. The dry methods are usually related to vacuum processes, such as physical vapor deposition (PVD) methods like sputtering, evaporation and sublimation, and chemical vapor deposition (CVD) methods. Although these dry methods have been well developed, some wet methods, such as spray, printing and electrochemical deposition, have been developed as well due to their low costs and simple procedures.

Among these wet processes, the spray and printing methods have been applied in manufacturing thin film solar cells. For example, NanoSolar developed a printing process to fabricate CIGS solar cells. This process has to prepare nanoparticles through complicated procedures and has to use some special procedures to concentrate CIGS nanoparticles compactly on the substrates. Otherwise, the films may become porous after the solvent is evaporated. An electrochemical deposition method plates metals from their salt electrolyte solutions onto some conductive or even non-conductive substrates with quantitatively controlled amounts and high quality of surface morphology. This non-vacuum procedure has a lot of advantages over those high-vacuum methods. For example, the surface morphology of a plated metal may be optimized with modification of a solution composition, and some micro-defects on the substrate surfaces may be filled up with the plated metals since the plating solution may fully soak onto the whole interior surfaces of those micro-channels. Driven with the Coulomb force, the metallic cations are attracted onto substrate surfaces and reduced to their atoms that are compactly aligned to form high quality of metallic films. Moreover, the electrodeposition methods can produce large area metallic films with uniform thickness that is still a big problem for most of high vacuum deposition. An electrochemical method also possesses some disadvantages. For instance, the electroplated materials may be restricted by their reduction potentials and sensitive to some specific substrates due to the interaction among different materials. Moreover, a hydrogen evolution is always a problem in a cathodic electrodeposition. In spite of these disadvantages, the electroplating methods are still extensively used to deposit the CIGS films. For example, SoloPower has been successfully using electroplating methods to deposit CIGS absorbers. In particular, the different materials, such as copper, indium, gallium and selenium, can be co-deposited onto a conductive substrate to form a CIGS film. Although many investigations about the electrochemical co-deposition of CIGS films were published or patented, they are difficult to be applied in an industrial manufacture process due to a difficulty in controlling composition and uniformity of a plated CIGS film. Accordingly, the electroplating procedures to deposit a layer-by-layer CIGS film may be more practical to manufacture CIGS solar cells.

Both of CIGS and CdTe solar cells contain a stack of absorber/buffer thin film layers to create an efficient photovoltaic heterojunction. A metal oxide window containing a highly resistive layer, which has a band gap to transmit the sunlight to the absorber/buffer interface, and a lowly resistive layer to minimize the resistive losses and provide electric contacts, is deposited onto the absorber/buffer surface. This kind of design significantly reduces the charge carrier recombination in the window layer and/or in the window/buffer interface because most of the charge carrier generation and separation are localized within the absorber layer. In general, CIGS solar cell is a typical case in Group IB-IIIA-VIA compound semiconductors comprising some of the Group IB (Cu, Ag, Au), Group IIIA (B, Al, Ga, In, Tl) and Group VIA (O, S, Se, Te, Po) elements of the periodic table. In particular, compounds containing Cu, In, Ga, Se and S are generally referred to as CIGS(S), or Cu(In,Ga)(S,Se)₂ or CuIn₁₋ₓGaₓ(S_{y}Se_{1-y})ₙ, where 0≦x≦1, 0≦y≦1 and n is approximately 2, and have already been applied in the solar cell structures that gave rise to conversion efficiencies over 20%. It should be noted that although the chemical formula for CIGS(S) is often written as Cu(In,Ga)(S,Se)₂, a more accurate formula for the compound is Cu(In,Ga)(S,Se)ₙ, where n is typically close to 2 but may not be exactly 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1. Here, the molar ratios of Ga/(Ga+In) and Cu/(Ga+In) are very important factors to determine the compositions and the conversion efficiencies of the CIGS solar cells. In general, a good solar cell requires a ratio of Cu/(Ga+In) between 0.75 and 0.95, and Ga/(Ga+In) between 0.3 and 0.6. In comparison with CIGS, the composition of a CdTe solar cell is much simple. In general, the content of Cd is close to 50% in the CdTe films. However, the Cd content may change after the deposition of a CdS layer and the subsequent annealing procedure. Close to the interface of the p-n-junction, for example, a CdSₓTe₁₋ₓ layer is formed with x usually not exceeding 0.06. However, x has a range changing from 0 to 1, which results in a compound from CdTe (x=0) to CdS (x=1).

In a procedure of electroplating the CIGS absorbers with layer-by-layer manners, Cu, In, Ga and Se are plated onto the substrates with different orders to form various stacks, such as Cu/Ga/In/Se, Cu/In/Ga/Se, In/Cu/Ga/Se, Ga/Cu/In/Se, Cu/Se/In/Ga, In/Se/Cu/Ga, Cu/In/Se/Ga, and so on. The different metals can also be plated more than once to generate more multi-layer stack combinations such as Cu/In/Cu/Se/Ga, Cu/Ga/Cu/In/Se/Ga/In/Cu, Ga/Cu/In/Cu/In/Ga/Se/Cu/Se, and so on. Furthermore, the single elements can be combined with electroplated alloys to form various stacks like Ga—In/Cu/Ga/Se/In/Cu—Ga, Cu—In/Ga/Cu/Se/In/Ga/Se, Cu—Ga/In/Cu/Ga/Cu—Se/In/Se, etc. Similarly, a CdTe absorber can be stacked in a similar way but with a simpler combination due to fewer components. After the electroplating, these combined stacks have to be annealed with a temperature ramp up to a few hundred degrees to convert these multi-layer metallic materials into uniform p-type CIGS or CdTe semiconductor absorbers. On this CIGS semiconductor absorber, an n-type semiconductor buffer layer such as CdS, ZnS, or In₂S₃ should be deposited. By contrast, a CdTe absorber may require only CdS buffer layer. After then, transparent conductive oxide (TCO) materials, i.e., ZnO, SnO₂, and ITO (indium-tin-oxide), should be deposited to form the solar cells.

Although the electroplating baths and methods of the CIGS and CdTe films have been well developed, the electroplating tools for industrial manufacture seem to be still in the traditional styles. In general, the electroplating of the substrates is carried out inside electroplating baths through piece-by-piece or bath-by-bath procedures. Continuous electroplating procedures have been developed as well. For example, Sergey Lopatin and David Eaglesham patented “Electroplating on Roll-to-Roll electroplating on Solar Cell Substrates” in 2008, and Bulent Basol also patented “Roll-to-Roll Electroplating for Photovoltaic Film Manufacture” in the same year. Moreover, some equipment companies of solar cells also produced some roll-to-roll electroplating production lines. However, all of these roll-to-roll electroplating apparatus are fixed to some pre-designed plating procedures. As discussed in the previous paragraphs, the most successful industrially scaled electroplating of the CIGS thin films are conducted with the multiple layers of single elements. In particular, the different plating orders of metal layers may produce totally different CIGS or CdTe absorbers after annealing. However, different metals require different plating conditions, especially different current densities that determine the lengths of the plating cells. As a result, these pre-designed electroplating apparatus cannot be easily changed to fit a different plating order. Therefore, a new electroplating apparatus for fabrication of multi-layer CIGS or CdTe absorbers with removable plating baths and changeable plating cells is present. With this electroplating tool, the plating baths and the cells can be simply assembled to change the plating orders of different metals.

### SUMMARY OF THE INVENTION

The present invention provides a roll-to-roll or reel-to-reel flexible electroplating apparatus to deposit multiple layers of different metals on thin continuous sheets of conductive substrates such as stainless steels, aluminum and so on. This apparatus consists of a series of modular electroplating sections the lengths of which can be readily adjusted to meet the requirements of different current densities required by various plating bathes. In addition, the removable bath tanks can be simply assembled to different modular plating sections. For a multiple layers with different metals, as a result, the metal plating orders can be easily changed. This may be particularly useful for electroplating p-type semiconductive absorber layers in Group IB-IIIA-VIA and Group IIB-VIA thin film solar cells if the electroplating is carried out with a layer-by-layer manner. In such a case, changing a metal plating order may significantly affect the resultant semiconductor quality. This apparatus can also be used as a general tool in different applications requiring layer-by-layer electroplating with different metals or semiconductors in a roll-to-roll or reel-to-reel process.

### BRIEF DESCRIPTION OF THE DRAWING

FIG. 1 shows a modular section in the apparatus to electroplate Group IB-IIIA-VIA or Group IIB-VIA absorber layers onto a flexible conductive substrate through a roll-to-roll or reel-to-reel process.

### DETAILED DESCRIPTION OF THE INVENTION

The present invention provides a production apparatus for electroplating multiple layers of Group IB-IIIA-VIA or Group IIB-VIA elements or their alloys to form thin film solar cell precursor stacks, in a roll-to-roll or reel-to-reel process, for manufacturing CIGS or CdTe solar cell absorbers on flexible conductive substrates. In particular, the present invention provides such a production line that can be flexibly assembled with a series of modular electroplating sections. The length of plating cell in every modular section can be adjusted to meet the special requirements of applied current densities. In addition, the solution tanks are removable. With these designs, this production apparatus is suitable for electrodepositing multiple layers of different metals or their alloys with changeable orders in a roll-to-roll process.

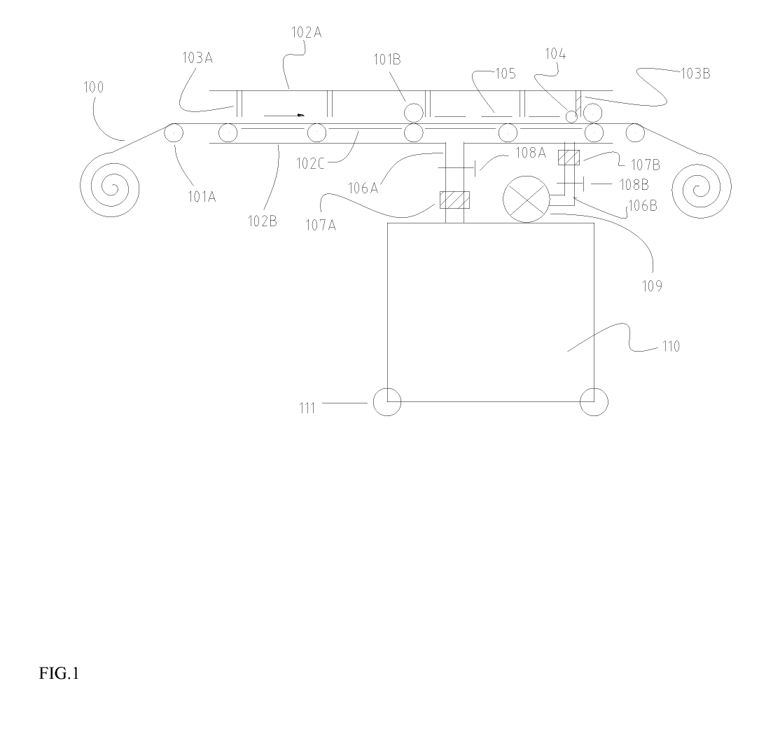

FIG. 1 shows one of the modular sections in a production line. The whole apparatus can be assembled with multiple modular sections. Between every two modular sections, one washing section shall be inserted. This washing section contains nozzles to wash both sides of the flexible substrates to make sure that a clean surface is brought into the next electroplating modular section. There are also some electrically conductive rollers or brushes fixed inside the washing sections to conduct current. At the end of the electrodeposition, the substrate will be washed and dried.

As shown in FIG. 1, the flexible conductive substrate 100 is delivered into a modular electroplating section from left to right along the arrow direction. The rollers 101A are arranged under the substrate to support it and the soft rollers 101B are on the top of the substrate just outside of the top plating cell to avoid the electrolyte solution flowing out without damaging the plated layers. 102A and 102B represent the top edge and the bottom of the modular section. 102C is the bottom of the plating cell. It is half to a few centimeters under the substrate 100. 103B is a fixed right edge of the top plating cell. 103A stands for several pairs of grooves on the both walls of the modular section above the substrate 100. Between a pair of grooves, a board can be tightly inserted to hold the solution inside the top plating cell between 103B and this 103A. By placing this isolating board to the other pairs of grooves, one can adjust the length of the top plating cell to meet the requirement of the applied current densities. Inside the top electroplating cell, the net anode modules 105 can be fixed parallel above the flexible substrate. A longer top plating cell requires more anode modules. These chemical resistant net anode modules are porous to allow the gas escaping from the plating baths. There is a pipe 104 with a dead end on one side and some small holes on the body. The other open end of this pipe is connected to the pipe 106B through a quick connecting adaptor 107B. The electrolyte solution shall be delivered with the pump 109 from the solution tank 110 to the pipe 104, and then flowing back to the tank through the pipe 106A. The hole diameters, density and arrangement in the pipe 104 shall be carefully designed to meet the requirements of electroplating hydrodynamics. Two valves 108A and 108B are used along with the pump 109 to hold enough solution inside the top plating cell. A filter (not shown in FIG. 1) can be connected between the valve 108B and the pump 109 or another location to filter the plating solution. The solution tank 110 may be easily disconnected from this modular section with the quick connecting adaptors 107A and 107B and moved away through four wheels 111 installed under the bottom of the tank.

### Example 1

### Electroplating of a Copper Layer onto a Molybdenum Surface Coated on a Stainless Steel Roll at a High Current Density

A one foot wide stainless steel roll coated with a molybdenum layer was loaded. It was delivered from left to right through an electroplating modular section as shown in FIG. 1 at a speed of 1 meter per minute. An aqueous electroplating copper solution containing 0.1 M Cu²⁺ in 6% H₂SO₄ was loaded into the tank 110, delivered into the top electroplating cell through the pump 109, the pipe 106B and the pipe 104, and then flowing back to the tank through the pipe 106B. To plate Cu at a high current density, a board was inserted into a pair of groove 103B that is close to the right wall 103A to build a short plating cell which might contain only one piece of the net anode module. A soft roller 101B was put outside the left of the top cell to avoid the solution flowing out. On the purpose of reducing gas generation and remain the Cu²⁺ concentration in the bath, some pieces of pure copper were put on the top of the net anode. This set-up remains the plating solution inside the top cell very well. A constant current between 20 and 40 A was applied onto this electroplating modular section to plate about 100 nm thick Cu layer onto the Mo surface. The film looks nice and no much gas bubbles were generated during the plating due to application of the soluble anode.

### Example 2

### Electroplating of a Copper Layer onto a Molybdenum Surface Coated on a Stainless Steel Roll at a Low Current Density.

The same materials and the plating bath was applied in this example. To meet the requirement for a low plating current density, the length of the top plating cell was increased by placing the isolation board at a pair of grooves 101B far away from the right wall 101A. Several pieces of the net anode modules 105 were connected. No copper piece was used as a soluble anode in this case. The substrate delivery speed and the applied constant current were the same as described in Example 1. Since the top plating cell length was a few times longer than the one in Example 1, however, the plating was carried out at a much lower current density.

As described above, this apparatus can be manufactured to deposit Group IB-IIIA-VIA or Group IIB-VIA solar cell absorber stacks onto the flexible conductive substrates with different widths. It can also be used to electrodeposit multiple layers of different metal or semiconductor stacks through a roll-to-roll or reel-to-reel process in other applications.

I claim:

1. An electroplating apparatus that can be assembled with modular electroplating sections to deposit multiple layers of metals and/or semiconductors and their alloys onto the flexible conductive substrates via a roll-to-roll or reel-to-reel process.

2. A production line or apparatus in claim 1, including:
1 to 50 modular electroplating sections
net anode modules fitted to the different lengths of the plating cells;
the plated metals from Group IB, IIB, IIIA and VIA;
the plated metals and semiconductors from Group IIA, IVA and VA;
other plated transition metals from the other B Groups Besides Group I and IIB;
the flexible conductive substrates such as stainless steels, aluminum, copper, molybdenum, nickel, zinc, titanium;
the flexible non-conductive substrates, i.e., polymers, plastics and other thin films, coated with conductive layers such as different metals or semiconductors.

3. A production line or apparatus in claim 1, which can be used to manufacture CIGS and CdTe thin film solar cells.

4. A modular electroplating section in claim 1, including:
changeable plating cell lengths to meet the requirements of various current densities;
the top plating cell lengths ranging from 0.1 to 2 meters;
the top cell width ranging from 0.1 to 2 meters;
movable electrolyte solution tanks with the wheels;
quick connecting/disconnecting designs between the electroplating cells and the solution tanks

5. A method of fabricating CIGS and CdTe thin film solar cells by electroplating multilayer CIGS or CdTe stacks, comprising:
applying cathodic currents to the flexible substrates delivered through the production line or apparatus described in claim 1;
plating different elements and/or their alloys in various orders through the production line or apparatus described in claim 1 and the modular section described in claim 4.
